(19) United States
(12) Patent Application Publication
(10) Pub. No.: US 2016/0208378 A1
(43) Pub. Date: Jul. 21, 2016

(54) METHODS OF FORMING LAYERS

(71) Applicant: SEAGATE TECHNOLOGY LLC, Cupertino, CA (US)

(72) Inventors: Philip George Pitcher, Shakopee, MN (US); Edwin Frank Rejda, Bloomington, MN (US); Richard Thomas Greenlee, Hastings, MN (US)

(21) Appl. No.: 14/944,795

(22) Filed: Nov. 18, 2015

Related U.S. Application Data
(63) Continuation of application No. 13/440,068, filed on Apr. 5, 2012, now abandoned.
(60) Provisional application No. 61/472,833, filed on Apr. 7, 2011.
(60) Provisional application No. 61/472,819, filed on Apr. 7, 2011.
(60) Provisional application No. 61/472,847, filed on Apr. 7, 2011.

(51) Int. Cl. C23C 14/48

(52) U.S. Cl. CPC C23C 14/48

(57) ABSTRACT

A method of forming a layer, the method including providing a substrate having at least one surface adapted for forming a layer thereon; directing a particle beam towards the surface of the substrate, the particle beam including particles, wherein the particle beam has an angle of incidence with respect to the substrate, and is configured so that the particles have implant energies that are not greater than about 100 eV; changing the angle of incidence of the particle beam, the implant energy of the particles, or a combination thereof; and directing the particle beam towards the surface of the substrate a subsequent time, wherein the particles of the particle beam form a layer on the substrate.

### PRIORITY

This application is a continuation of U.S. application Ser. No. 13/440,068, filed Apr. 5, 2012, which claims priority to U.S. Provisional Application No.: 61/472,833 entitled “NANO-PROCESING TECHNIQUE TO CONTROL FILM PROPERTIES”, having docket number 16151.01 filed on Apr. 7, 2011; 61/472,819 entitled “SURFACE SUB-PLANTATION TECHNIQUE TO CONTROL NANOMETER SCALE COC FILM PROPERTIES”, having docket number 16157.01 filed on Apr. 7, 2011; and 61/472,847 entitled “LOW ENERGY GONIOKINEMATIC NANOENGINEERING PROCESSING & HARDWARE”, having docket number 16900.01, filed on Apr. 7, 2011.

### BACKGROUND

In nanoscale surface/surface region engineering, typical implantation/sub-plantation energies (for example energies of ≧100eV) produce, in addition to implanted particles, damage centers e.g. displaced atoms, vacancies and recoils, recoil mixing on a length scale significant to the interface of the formed layer with the sub-surface layer. These effects interact with the mechanisms of film growth and have continuous effects as the film growth proceeds. For very thin films or surface layers the effects are seen throughout the thickness of the layer and affect the structural and compositional characteristics. When considering carbon containing films or layers, the effects can affect development of sp3 and sp2 centers. These factors, compounded by the statistical nature of the range distribution and the probability of occurrence of these kinematical events complicate the ability to engineer films having a desired sp3/sp2 ratio. Therefore, there remains a need for implantation/sub-plantation techniques for producing films having thicknesses on the nanometer scale range thickness (<30A).

### SUMMARY

A method of forming a layer, the method including providing a substrate having at least one surface adapted for forming a layer thereon; directing a particle beam towards the surface of the substrate, the particle beam including particles, wherein the particle beam has an angle of incidence with respect to the substrate, and is configured so that the particles have implant energies that are not greater than about 100 eV; changing the angle of incidence of the particle beam, the implant energy of the particles, or a combination thereof; and directing the particle beam towards the surface of the substrate a subsequent time, wherein the particles of the particle beam form a layer on the substrate.

A method of forming a layer, the method including providing a substrate having at least one surface adapted for forming a layer thereon; implanting a material from a particle beam into the surface of the substrate for a time t1, the particle beam having a first angle of incidence, α1 with respect to the surface of the substrate, and the particle beam being configured so that the particles have implant energies that are not greater than about 100 eV; changing the angle of incidence of the particle beam to a second angle of incidence, α2; and implanting the material from the particle beam into the substrate for a time t2, the particle beam having the second angle of incidence α2, thereby forming a layer, wherein the times t1 and t2 and the angles of incidence α1 and α2 are chosen to produce a linear concentration depth profile of the material in the layer.

A method including inserting an incident species into the surface layer of atoms on a substrate so that the incident species are inserted to within 30 Å of the surface.

The above summary of the present disclosure is not intended to describe each disclosed embodiment or every implementation of the present disclosure. The description that follows more particularly exemplifies illustrative embodiments. In several places throughout the application, guidance is provided through lists of examples, which examples can be used in various combinations. In each instance, the recited list serves only as a representative group and should not be interpreted as an exclusive list.

### BRIEF DESCRIPTION OF THE FIGURES

FIG. 1 shows an example of a disclosed sub-implantation through an acetylene ion beam.

FIG. 2 illustrates how surface implantation can modulate surface density through insertion and displacement effects.

FIGS. 3A and 3B show simulation results for implanted argon into a carbon film at 65° (FIG. 4A) and 78° (FIG. 4B).

FIGS. 4A and 4B depict a theoretical illustration of a disclosed method that includes the incremental step process concept.

FIG. 5 shows a flow chart depicting an exemplary embodiment of a disclosed method.

FIGS. 6A, 6B, 6C, and 6D show the film compressive stress of a film formed using a disclosed method relative to conventional methods (FIG. 6A); the wear resistance and coefficient of friction (COF) (FIG. 6B), a Raman spectrum of a film formed using a disclosed method (FIG. 6C) and a Raman spectrum of a film formed using pulsed filtered cathodic arc technique (pFCA) (FIG. 6D).

FIG. 7 shows wear resistance of a film formed using disclosed methods and a film produced by (pFCA).

FIG. 8 shows in-situ visible Raman peak intensities at ambient air and temperature.

FIGS. 9A and 9B show in-situ hot RW-TTF tests for films that have 7.9 Å A1 and 15.9 Å C produced by pFCA (FIG. 9A) and films formed using disclosed methods (FIG. 9B).

FIGS. 10A, 10B, 10C, and 10D show a Raman spectrum of an as deposited 17 Å film formed using a disclosed method (FIG. 10A); after annealing at 250° C. for two hours (FIG. 10B); after annealing at 250° C. for four hours (FIG. 10C); and in graphical format (FIG. 10D).

FIG. 11 shows photos of films deposited using pFCA (left photos) and films deposited using disclosed methods (right photos) after being subject to a bar level Hysitron Wear box and thermal corrosion test.

FIGS. 12A, 12B, 12C, 8D, and 12E show the results of advanced friction testing (FIG. 12A);

the friction slope (rate of change with power) for a film produced with pFCA (FIG. 12B) and a film produced with SSP (FIG. 12C); and photos of films (a film produced with pFCA (FIG. 12D) and a film produced using disclosed methods (FIG. 12E)) on transducers after being burnished.

FIGS. 13A and 13B show the life (days) with increasing temperature (deg C) by Bit Error Rate (BER) metric of a film formed using pFCA (FIG. 13A) and a film formed using disclosed methods (FIG. 13B).

FIGS. 14A and 14B show film stress as a function of the deposition angle for a 15 Å film (FIG. 14A) for a 22 Å film (FIG. 14B).

FIGS. 15A and 15B show film stress as a function of the deposition angle for a 15 Å film (FIG. 15A) for a 19 Å film (FIG. 15B).

FIG. 16 shows the film stress as a function of the thickness of the film.

FIG. 17 shows the film stress as a function of beam current.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

“Include,” “including,” or like terms means encompassing but not limited to, that is, including and not exclusive. It should be noted that “top” and “bottom” (or other terms like “upper” and “lower”) are utilized strictly for relative descriptions and do not imply any overall orientation of the article in which the described element is located.

Disclosed herein are methods, processes, and systems to extend and improve surface nanoengineering technologies. Disclosed methods offer surface sub-plantation (SSP) and interfacial engineering for example using various methods and techniques including monoatomic or polyatomic molecular ions or cluster ions. In disclosed methods processing occurs at depth scales ranging from sub-monolayer to a few bond lengths from the surface. Applications include surface modification, materials synthesis, and compositional modifications on a depth scale extending a few nanometers from the surface, etching and interfacial engineering. Both carbon and hydrogenated carbon layers are specifically discussed herein, but the disclosed methods and considerations are applicable to other materials, including metastable surface compositions or surface layers. One of skill in the art, having read this specification, will understand that the disclosed methods are applicable to materials other than carbon and hydrogenated carbon.

“Layer” as utilized herein can refer to material on the surface of a substrate, material at the interface of the substrate (i.e. materials partially implanted into the surface but also exposed as if on the surface), material within the substrate (i.e. materials implanted into the substrate and not exposed at the surface of the substrate), or any combination thereof. Formation of a layer can therefore include implantation of the material in the bulk of the substrate (typically only to a depth of a few nanometers or less below the surface); implantation of the material at the surface of the substrate (e.g., partially embedded in the substrate); deposition of the material on the surface of the substrate (or on material that has already been formed by a disclosed method); or combinations thereof. It should also be noted that as a layer is formed, the surface is continuously moving upward away from the substrate. A “film” as utilized herein can refer to material that exists on the surface of the substrate. A layer may therefore include only a film or a film and material within the substrate. Methods disclosed herein can be utilized to form layers. The formation of layers utilizing disclosed methods can include surface modification, materials synthesis, compositional modifications, or combinations thereof. Formation of layers, as disclosed herein can include process interactions that may be confined to surface layer atoms or to within a few bond lengths from the surface. Formation of layers utilizing disclosed methods can also be referred to as surface sub-plantation (SSP).

Disclosed methods and processes may minimize or limit “undesirable effects” of layer formation to the first few atomic layers from the surface. Methods and processes disclosed herein can be described as confining the interaction of process particles (those being implanted, deposited, or both) with the underlying sub-surface to only a few bond lengths from the surface. The “few bond lengths” continuously moves (towards the surface) as growth proceeds. Methods and processes disclosed herein can also be characterized as controlling the exchange or coupling of energy from the process particles (those being deposited) into the surface or near surface region so that the underlying material is not detrimentally affected.

Methods and processes disclosed herein can alternatively be characterized as enabling insertion of incident species into the surface layer of atoms to within 30 Å from the surface. In some embodiments, disclosed methods and processes can enable insertion of incident species into the surface layer of atoms to within 20 Å from the surface. In some embodiments, disclosed methods and processes can enable insertion of incident species into the surface layer of atoms to within 15 Å from the surface. In some embodiments, disclosed methods and processes can enable insertion of incident species into the surface layer of atoms to within 10 Å from the surface. The phrase “first few atomic layers from the surface” or a particular measurement (for example “within 30 Å from the surface”) from the surface are meant to refer to the top atomic layers of a near surface layer, those that are closest to the deposition/implantation surface.

Undesirable effects that can be avoided or minimized using disclosed methods and processes can include for example damage centers or more specifically displaced atoms; defect generation and recombination; vacancies and recoils; recoil mixing on a scale significant to the interface of the deposited layer with the sub-surface layer; thermal dissipation of kinetic energy from deposited ions which can anneal desired properties (for example sp3 centers in carbon containing films) from the layer; sputtering; incident particle reflection; heat generation; and implantation (and intrinsic) induced defects that can enhance thermal relaxation of localized induced strain by defect center migration which can anneal desired properties (for example sp3 centers in carbon containing layers) from the layer; and any combination thereof. Disclosed processes and methods can avoid or minimize such effects, can confine them to the first few atomic layers from the surface, or both.

Disclosed methods can be utilized to engineer the composition of a layer. For example, disclosed methods can be utilized to engineer a carbon containing layer (it is noted that a carbon containing layer is utilized as an example only and compositional engineering can be undertaken with any type of material). It is also noted that compositional engineering can be utilized to form a carbon containing layer and/or a hydrogenated carbon containing layer. Application of disclosed processes or methods to the deposition of carbon containing layers can allow the sp3/sp2 ratio of the layer to be engineered. “sp3” and “sp2” refer to types of hybridized orbitals that a carbon atom (for example) may contain. An sp3 carbon atom is bonded to four other atoms, such as four other carbon atoms because it contains four sp3 orbitals, a sp3 orbital forms a very strong σ bond to another carbon atom for example. An sp2 carbon atom is bonded to three other atoms, such as three other carbon atoms because it contains three sp2 orbitals, a sp2 orbital forms a π bond that is weaker than a σ bond. In numerous applications, including carbon overcoats that are used in magnetic recording heads and media, carbon having more sp3 than sp2 bonds can often be desired because the carbon is more stable (i.e., it contains stronger bonds). In some embodiments, disclosed processes or methods can allow formation of a carbon containing layer that is more stable, i.e., has more sp3 bonds than sp2 bonds. Such carbon layers can have higher thermal resiliency, better mechanical properties, better chemical characteristics, or combinations thereof.

Incident hyperthermal particles can penetrate the surface potential barrier through either insertion in sites between existing atoms and/or through displacing existing atoms with the production of a non-recombining recoiling atom to induce localized increase in atomic density. Local atomic reconfiguration and sp3 bond hybridization can occur to accommodate the presence of the non-equilibrium hyperthermal and displaced particles and the resulting induced localized distortion/strain. Disclosed methods can achieve this in a very thin layer contained within a few bond lengths of the surface. In addition, the energetics can be adjusted to try to minimize instantaneous recombination and the production of thermal energy which can act to annihilate or anneal out, respectively, the sp3 centers.

It should also be noted that two other applications directed to similar and further processes and methods for forming layers are being filed on the same day as this application: “METHODS OF FORMING LAYERS” having docket number 430.16157010, U.S. patent application Ser. No. ______ , Philip Pitcher et al.; and “METHODS OF FORMING LAYERS” having docket number 430.16900010, U.S. patent application Ser. No. ______ , Philip Pitcher. The disclosures of which are incorporated herein by reference thereto.

Some disclosed methods include processing or depositing low energy particles in order to minimize the undesired effects of implantation. The following construct can be utilized herein in order to explain the energy of the particles. In the exemplary case of a grounded beam particle source, the incident energy (V_{inc}) of a particle immediately prior to its interaction with an unbiased, uncharged substrate surface is given by the sum of the beam voltage (or screen bias), V_{b}, and the plasma potential, Vₚ, assuming the incident particle is a monoatomic, singly charged ion. In this instance, the implant energy (Vᵢₘₚ) is the same as the incident energy (V_{inc}) as described. For the case of a singly charged molecular ion or cluster, it is assumed that upon interaction with atoms at the substrate surface, molecular orbital overlap results in complete fragmentation of the molecule (or cluster) into its component atomic species. The incident kinetic energy (V_{b}+Vₚ) minus the molecular or cluster dissociation energy is then partitioned over each atomic “fragment” according to its mass fraction (mass_{atomic component}/mass_{total molecule or cluster}) of the original incident molecular or cluster mass to give Vᵢₘₚ of each fragment.

The implant energy of a particle can be selected (the maximum is selected) to restrict the ion projected range into the surface to less than a maximum of a few bond lengths. The implant energy of a particle can also be selected (the minimum is selected) to be at least sufficient to allow penetration of the surface energy barrier to allow incorporation of the particles into the surface. Because of the minimum energy selected (enough to allow penetration of the particle into the substrate), growth of the layer is not accomplished via typical nucleation growth mechanisms. The chosen range of implant particle energies being such that kinematic energy transfer to target atoms is either insufficient to produce displacement or, on average, to generally produce only one or two displacement reactions or sufficient to allow insertion into the surface or to distances within a few bond lengths from the surface.

In some embodiments, disclosed methods include utilizing particles having implant energies of tens (10s) of electron volts (eV). In some embodiments, methods include utilizing particles having implant energies of less than about 100 eV. In some embodiments, methods include utilizing particles having implant energies of not greater than about 80 eV. In some embodiments, methods include utilizing particles having implant energies of not greater than about 60 eV. In some embodiments, methods include utilizing particles having implant energies of not greater than about 40 eV. In some embodiments, methods include utilizing particles having implant energies of not greater than about 20 eV. In some embodiments, methods include utilizing particles having implant energies from about 20 eV to about 100 eV. In some embodiments, methods include utilizing particles having implant energies from about 20 eV to about 80 eV. In some embodiments, methods include utilizing particles having implant energies from about 20 eV to about 60 eV. In some embodiments, methods include utilizing particles having implant energies from about 20 eV to about 40 eV.

At the disclosed low implant energies further complications can exist with the practical implementation of disclosed methods because of the interaction of the low implant energy particle cross-section with multiple rather than single surface atoms resulting in complex, indeterminate many body collision kinematics and enhanced defect recombination rates through low kinematic energy exchange(which may act to reduce sp3 center generation).

Techniques for the production of highly controlled particle beams are well developed for the ion implantation and etch technologies (KeV energy range) and in the sputter deposition or evaporation deposition regime (<about 15 eV). In contrast, technology is much less developed for energies of approximately tens of electron volts (eV) which are of interest in disclosed methods. At these energies, technological constraints can result principally through space-charge interactions between ions in the beam. These effects can limit the generation of practicable beam currents (densities) and the quality of the beam ion-optical characteristics that can be important in, for example, focusing and mass selection. Generally, the required beam characteristics at energies of only a few tens of eV are outside the operational envelopes of broad beam ion sources, the mainstay of many conventional dry processing techniques.

Disclosed methods and systems enable application of commercially proven broad (or narrow) beam ion source technology to the low energy methods disclosed herein. The use of molecular ions in low energy ion beam processing techniques allows processing at energies within the ion energy design operation envelope of the ion gun at sufficient energies to allow usable beam currents. By partitioning the incident ions kinetic energy on a molecular ion it is possible to implant or sub-implant at lower implant energies than the incident ion energy, these energies not normally practically accessible with typical ion gun physics. The implant molecular or cluster ion energy is selected to be sufficient to overcome barriers to low energy sub-implantation or surface processing e.g. ion reflection and/or surface potential barrier effects (as discussed above). As the incident particle approaches a substrate atom, instantaneous molecular or cluster fragmentation occurs as electron orbitals overlap, resulting in partitioning of the incident ion energy amongst the implanting/sub-implanting particle fragments (which can also be referred to herein as “component atomic species”). Appropriate selection of molecular ion species and incident energy allows proper engineering of the implant energy of the fragments to the desired energy for surface sub-plantation (SSP).

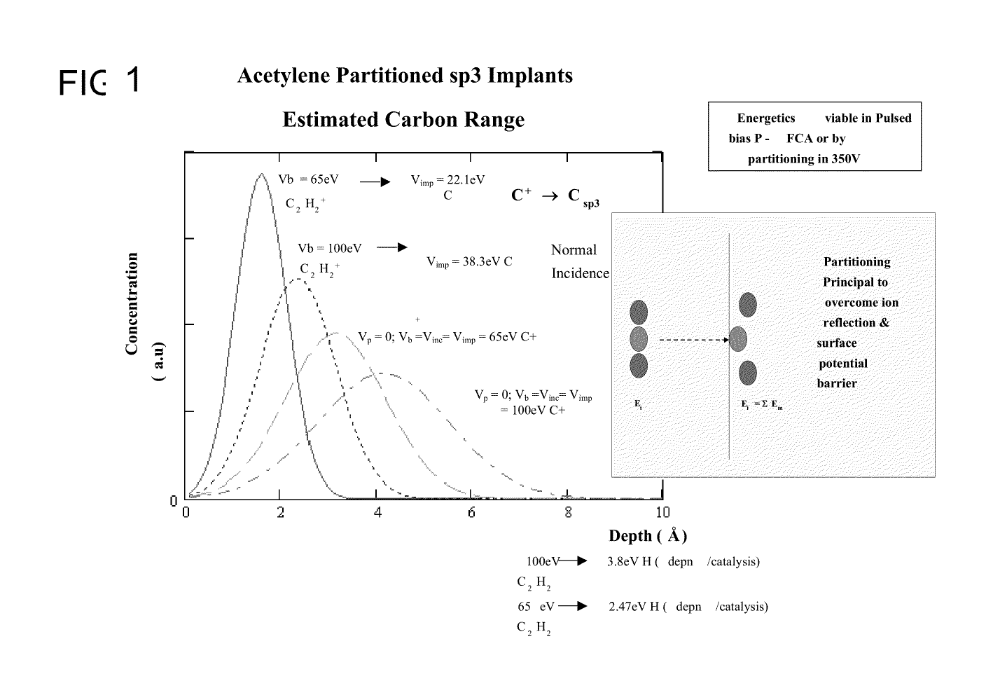

FIG. 1 compares the estimated carbon range (depth into the substrate) of both acetylene partitioned particles and carbon (non-partitioned) particles. FIG. 1 shows that partitioning of the ion energy upon fragmentation decreases the depth of interaction of the deposited species. Specifically, FIG. 1 shows that fragments from polyatomic species (C₂H₂+ in the example shown in FIG. 1) do not interact as deeply into the surface as ions directly formed from an ion beam (C⁺ in the example shown in FIG. 1). The energetics depicted in this example are viable in a pulsed bias P-FCA or by partitioning in 350 V. Note that through suitable control of the incident molecular ion energy, the secondary ion fragments, hydrogen in the case of FIG. 1, may or may not be incorporated into the growing layer. In the embodiment depicted in FIG. 1, the hydrogen would likely not be incorporated into the layer because the energies are not high enough (3.8 eV and 2.47 eV) to allow the hydrogen particles to enter the substrate. In some disclosed embodiments, suitable control of the ion beam current density may be exercised to control the defect introduction rate.

In molecular ion energy partitioning, limitations exist on the ability to control the nature of the incident species and therefore the kinematic processes. Such kinematic processes can be important in achieving new nanoengineering methodologies in nanomaterials synthesis, etch, interfacial nanoengineering, nanodoping and metastable surfaces (principally through the fragmentation process). These effects may limit, for example, the conversion efficiency of sp3 centers and therefore thermo-chemo-mechanical robustness that may be relevant to certain applications (for example heat assisted media recording (HAMR) overcoats). There is often a delicate balance in surface nanoengineering between process threshold effects, the available nanoprocessing window and competition from process disruptive elements. Indications of SSP process thresholds were given above in terms of molecular orbital interaction effects and kinematic thresholds for sp3 center formation. Phonons, produced through the kinematic process of sp3 center formation, act to annihilate sp3 centers by reducing localized strain excursions by thermal migration of atoms. Comparing the threshold energetics for sp3 center synthesis with an estimate of ion induced carbon atom jumps induced as a function of incident ion energy below clearly indicate the importance of process control in surface nano-engineering technology.

Alternative approaches to low energy processes, include substrate biasing (including high frequency biasing and pulsing), filtered cathodic arc (FCA) deposition techniques and altering the source potential in either ion beam deposition (IBD) or FCA techniques. Such approaches can be used singly or in combination. However, in all these techniques although some critical process elements may be easily controlled (for example, energy), typically, other key process control parameters for surface nanoengineering processes (for example the incident arrival angle spectrum) are not. Application may be best carried out with conductors, and stray field effects can limit the degree of control.

Also disclosed herein are optional methods and/or steps to improve low energy processing techniques utilizing the acceleration and/or deceleration of ions, which are referred to herein as “ion accel-decel” approaches. Such ion accel-decel approaches can be accomplished with mass selection, beam conditioning and shaping in conjunction with goniokinematic processing (coordinated real time variation of particle beam parameters with the goniometric (angle) disposition of the target process surface (with respect to the beam axis)) to control factors that afford control of process phenomena, for example etch, interfacial nanoengineering, nanodoping, surface nanoengineering of nanomaterials and metastable surface materials. Ion accel-decel approaches can circumvent low energy ion beam transport effects and poor ion source performance characteristics at low energies (e.g. unuseably low beam currents) to improve process control. Ions can be accelerated and conditioned at high energies and then decelerated to impact energy just prior to collision with a substrate. The existence limits for low energy processes can, however, be extremely narrow and easily corrupted.

Massive beam divergence can be exhibited by the beam (with probable loss of process control) if proper consideration of the “throw” distance to the substrate table is not made in instrument design together with proper control of deposition rate in the process window. Process control of particle energy, beam current, beam divergence, charge state and ion mass are typically static in conventional process techniques. However variation of selected beam parameters may be used to e.g. tailor interfaces, compositional or damage center concentration profiles with and without sample goniometric motions. In conjunction, variably doped multilayer nanostructures or selective depth or surface doping may be achieved by appropriate switching of the mass filter parameters during or post- film growth e.g. in lube engineering applications.

An advantageous use of a controlled low energy, mass filtered, collimated beam particle source with beam current control is in goniokinematic physicochemical processing techniques. These methods may prove pivotal in driving surface collisional processes to enable controlled nanoengineering of surfaces, interfaces and near surface regions. Goniokinematic processes require coordinated real time variation of particle beam parameters with the goniometric disposition of the target process surface (with respect to the beam axis). Such methods can for example help selectively control whether incident particles interrogate surface or sub-surface atoms and thereby interact with target atoms or chains of atoms through a surface interatomic potential or internal “bulk” interatomic potential or both. This in turn may determine the probability of achieving a desired surface collision or surface collision sequence or overcoming a potential barrier to a surface reaction. A particular profile of incident particle energies correlated to a select value or range of impact angles may be used for these purposes or to control a depth profile of implanted atoms e.g. in a doping concentration profile.

Narrow ion beams are typically electrostatically scanned over a substrate surface to produce a uniform ion dose. This will result in position variable angular registration of incoming ions with target atoms and therefore variations in collision kinematics, even for a fixed substrate position.

Furthermore, beam scanning can produce positional incident energy variation and positionally variable beam current densities even for fixed values of beam energy and beam ion current at the ion source on static substrates. Mechanical scanning techniques combined with beam shaping methods can ameliorate several potential goniokinematic process variation effects created by electrostatic scanning of spot particle beams. Examples include a particle beam formed into a thin “slot” like profile of uniform intensity and a substrate scanned in a vertical or horizontal axis with respect to the beam axis to achieve overall uniform illumination over the substrate area. Some scan systems may use a static slot beam profile combined with a high speed rotation of the substrate in conjunction with a slower lateral or longitudinal scan motion to achieve a uniform field of particle irradiation over the substrate area. Such techniques can allow constant incident areal particle density processing over the substrate field in contrast to beam scanning techniques even if the substrate is tilted. In low energy nano-engineering ion beam processing the variation in length of field free drift path (FFDP) produced by beam scanning alters not just the particle incidence angle but also could cause considerable alteration to the incidence beam divergence affecting critical goniokinematic process variables which are also inconsistent across the materials process plane. This is further compounded by a positionally variable areal particle density. Static, shaped, particle beams with substrate motion can be designed to allow goniometrically variable processing of the substrate at constant FFDP and incident particle areal density.

Methods disclosed herein can generally be referred to as surface sub-plantation (SSP). Such SSP methods can include processes and steps that enable insertion of incident species into a surface layer of atoms to within only about 30 Å from the surface. Disclosed methods are novel and advantageous because they do not interact with atoms that are deeper into the surface, for example they do not interact or do not appreciably interact with atoms that are deeper than about 30 Å into the surface. In some embodiments, disclosed methods are novel and advantageous because they do not interact or do not appreciably interact with atoms that are deeper than about 20 Å into the surface. In some embodiments, disclosed methods are novel and advantageous because they do not interact or do not appreciably interact with atoms that are deeper than about 15 Å into the surface. In some embodiments, disclosed methods are novel and advantageous because they do not interact or do not appreciably interact with atoms that are deeper than about 10 Å into the surface.

Disclosed methods can be utilized to form layers of any material; or stated another way incident species that are inserted into a surface layer can have any identity. In some embodiments, disclosed methods can be utilized to form layers that include carbon. In some embodiments, disclosed methods can be utilized to form layers that include carbon as a hydrocarbon (e.g., hydrogenated carbon). It should be understood however that carbon and hydrocarbons are simply an example and disclosed methods are not limited to formation of carbon and/or hydrocarbon layers or films.

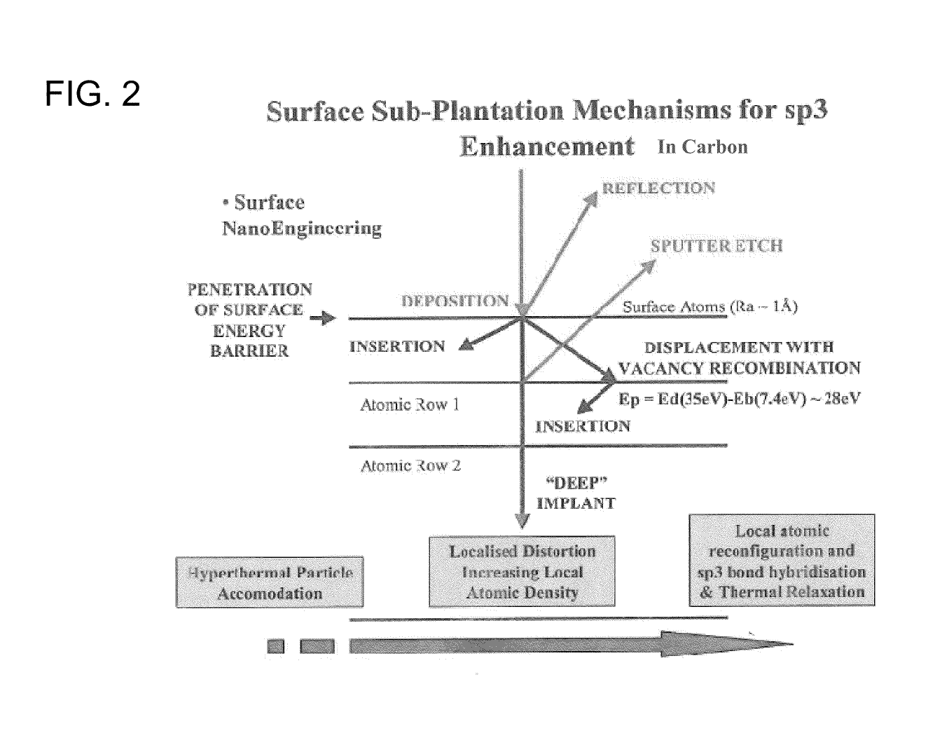

Disclosed methods strive to confine the processing effects to the top few bond lengths of the layer continuously, as growth proceeds. This can minimize or eliminate the effects of non-linear atomic interaction of implanting particles with substrate atoms (which may still be present when the angle of incidence is merely changed). FIG. 2 illustrates how surface implantation can modulate surface density through insertion and displacement effects. In some embodiments where a film including carbon is being formed, this can also modulate sp3 bond hybridization.

As seen in FIG. 2, surface implantation can be complicated by several mechanisms, including sputter etching, penetration of the surface energy barrier and ion reflection. A process energy window can be estimated from calculation estimates of these effects. For the case of a carbon implanted in a carbon or hydrocarbon substrate surface, size effects effectively determine the minimum energy for penetration; this is estimated from estimates of collision cross-sections to be about 20 to 25 eV. This is close to typical atomic displacement energies that correspond to the high energy tail of ion beam deposition (IBD) sputter deposition techniques. From a study of possible surface atom ejection mechanisms, a maximum arrival energy, for example from normal incidence, can be calculated to avoid excessive sputtering of the growing film and compared to predictions based on the energy dependence of the sputter coefficient. Sputtering, in part defines the upper energy limit (in certain embodiments) for the surface sub-plantation (SSP) technique. Both models predict minimal atomic ejection below about 40 to 42 eV. Practically, predictions from the energy dependence of the sputter yield indicate only about 10% surface sputter loss at about 60 eV, setting an effective “zero” sputter loss estimate for the upper process limit in some embodiments. In other embodiments, greater sputter losses may be tolerated or even desired, e.g., approximately 30-40% at implant energies of 80 eV in this example. It should be noted that the specific values discussed above apply onto the case of carbon; however the considerations apply to implantation of any material.

Disclosed methods can utilize low implant energy particles; or stated another way the incident species that are inserted into the surface layer can have low implant energies. In some embodiments, the low implant energy particles can have energies in the tens of electron volts (eV). This is in contrast to other methods that utilize particles having energies of hundreds or thousands of eV (typical ion implantation or etching); and methods that utilized particles having less than about 15 eV (sputter deposition and evaporation methods). In some embodiments, the particles can have implant energies that are not greater than about 100 eV, not greater than about 80 eV, not greater than about 60 eV, not greater than about 40 eV, or even about 20 eV. In some embodiments, the particles can have energies from about 20 eV to about 100 eV, from about 20 eV to about 80 eV, from about 20 eV to about 60 eV, or from about 20 eV to about 40 eV. It should also be noted that not all particles impacting a surface need have the same implant energies. For example in embodiments where molecular partitioning is utilized, different kinds of atoms (e.g., carbon and hydrogen) will have different implant energies.

In some embodiments, low implant energy particles can be formed from a broad beam ion source, or a narrow beam ion source for example. A specific example of a source of particles is an inductively coupled RF, gridded ion source. A source of particles is referred to herein as a particle beam.

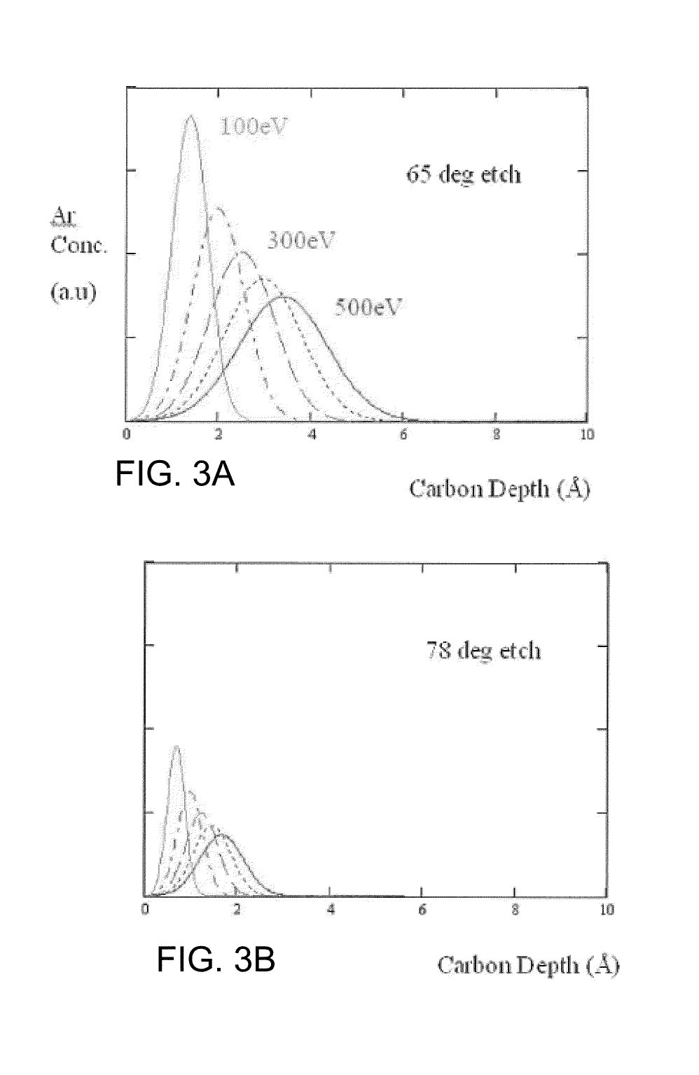

Disclosed methods can also utilize particle beams that are directed towards the surface of a substrate (upon which a layer is to be formed) at a particular angle or particular angles of incidence. The angle of incidence of the particle beam can be characterized with respect to the surface of the substrate. In some embodiments, the angle of incidence can be less than about 180°, in some embodiments less than bout 80° , and in certain embodiments, less than about 70°. FIGS. 3A and 3B show simulation results for implanted argon into a carbon film at 65° (FIG. 3A) and 78° (FIG. 3B). As seen there, as the angle of incidence increases, the depth that the argon atom reaches into the film also decreases.

Disclosed methods can also implant incident species at more than one angle of incidence in order to control and manipulate the distribution of implanted atoms. For example, a series of angles of incidence (which produce different angular depth profiles) can be superimposed in order to obtain a final desired composite depth profile. The depth limits of the distribution can be set through upper and lower angular limits of a sequential differential scan. In some embodiments, the angle of incidence can be scanned from 180° to 0° . In some embodiments, the conditions for producing a thin lamella, thickness Δx, of uniform concentration (C₀) of implanted atoms can be approximated by incrementally angularly separated processing. The angular profiles are separated by an incremental angle Δ_{φ}for a given ion-material, energy and concentration combination. By appropriate variation of the dwell time at each angle (separated by the incremental angle) the goniometric flux variation and goniometric ion range variation can be accommodated to produce a linear concentration depth profile. The “integrated” profile is almost independent of the process inherent angular concentration profile, excepting a small “error” due to range straggle. In fact, the incremental angle and dwell technique can be extended to produce a depth profile of almost any shape at a controlled depth location.

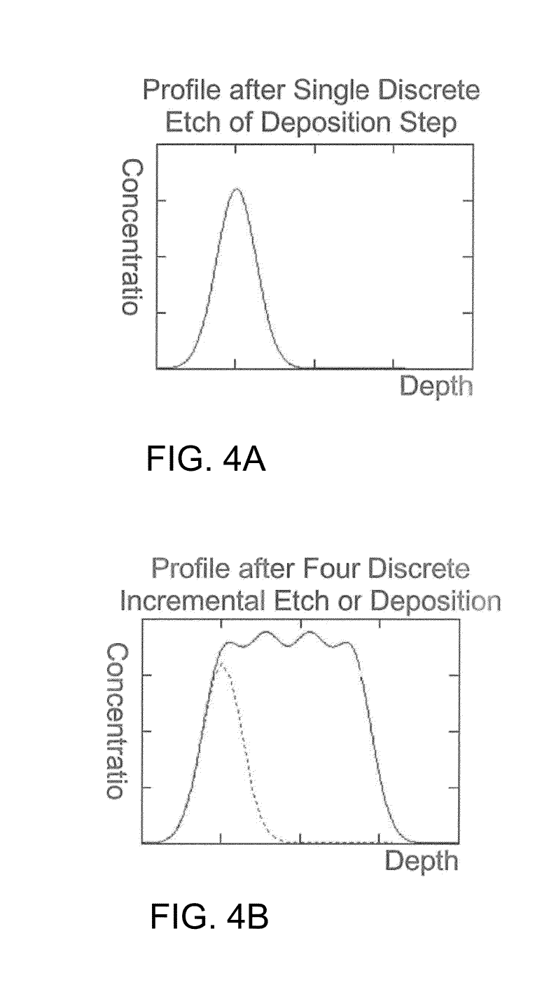

A theoretical illustration of this disclosed method is shown in FIGS. 4A and 4B through the incremental step process concept. Each incremental step has an associated depth profile. Multiple steps can be used to produce the desired final depth profile (as seen in FIG. 4B). The example below shows the basic concept that would improve the concentration profile as a function of depth as compared to a typical single discrete process step.

In disclosed methods, the particle beam can have an angle of incidence with respect to the substrate. In some embodiments, the angle of incidence can be less than about 80°, and in certain embodiments, less than about 70° with respect to the substrate. Disclosed methods may also include a step of changing the angle of incidence of the particle beam, the energy of the particles, or a combination thereof. Once the angle, the energy or the combination is changed, the particle beam is directed towards the surface again in order to implant incident species again. The steps of changing the angle, the particle's energy, or combination thereof and implanting particles again can be repeated a plurality of times or may be continuously variable.

In some embodiments, the angle can be scanned (either constantly or variably—in terms of time at a particular angle or distance between the angles, or both) from a minimum (e.g., 0°) to a maximum (e.g., 180°) using chosen dwell times and chosen increments. In certain embodiments, disclosed methods can also include changing the angle of incidence, energy of the particles, or a combination thereof a plurality of times; for example by scanning The angle of incidence, the range of the angle of incidence, (α₁-αₓ), the incremental change in the angle of incidence (Δα), the time at each setting (t₁-tₓ), the energy of the particles, or any combination thereof can be chosen to produce a desired concentration depth profile (for example a linear concentration depth profile) of the material in the film.

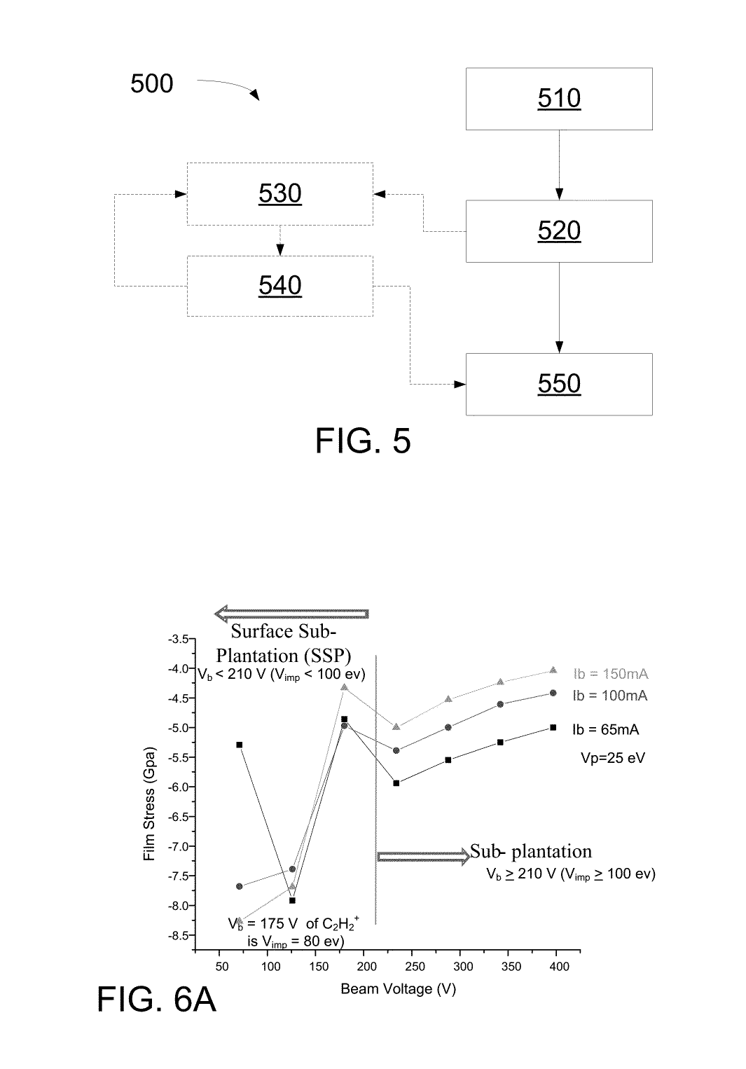

Disclosed methods can include various steps. An exemplary embodiment of a disclosed method is depicted in the flow chart in FIG. 5. The exemplary methods 500 depicted in FIG. 5 include the steps of providing a substrate, step 510; and the step of directing a particle beam at the substrate, step 520 in order to form a layer, which is indicated by 550. Exemplary methods can also include the optional steps of changing the angle of incidence 530; and directing the particle beam at the substrate again, step 540. As seen in FIG. 5, steps 530 and 540 can be repeated, in some embodiments, they can be repeated a plurality of times.

A more specific embodiments of a disclosed method includes for example: providing a substrate having at least one surface adapted for layer formation thereon; directing a particle beam towards the surface of the substrate, where the particle beam includes low impact energy particles and the particle beam has an angle of incidence with respect to the substrate; changing the angle of incidence or the impact energy of the particles of the particle beam or both; and directing the particle beam towards the surface of the substrate a subsequent time to form a layer on the substrate. Such methods can function to insert incident species into the surface layer of atoms to within 30 Å of the surface.

The substrate upon which the layer is to be formed can be any type of material or structure. In some embodiments, an exemplary substrate can have at least one surface upon which the layer formation will take place. Such a surface can be referred to as “being adapted for layer formation”, which can include simply being placed in a process chamber so that a layer will be formed on at least the desired surface. In some embodiments, the substrate can include structures or devices formed thereon or therein. In certain embodiments, methods disclosed herein can be utilized to form overcoats on various structures; and in such embodiments, the device upon which the overcoat is to be formed can be considered the substrate.

Various processes and procedures can optionally be carried out on the substrate before a layer is formed thereon. In certain embodiments, the surface of the substrate can be etched before a layer is formed thereon. A specific example of a pre-layer formation etch can include the following: a beam voltage (V_{b}) of about 300V; a beam current (I_{b}) of about 300 mA; 15 sccm Ar @ 40-80° incidence angles (e.g dual angles) from normal. Typically 10-100 Å can be removed by a single etch or multiple etches that may include changes to the energy, beam current, incident angle, gas composition variation, pulsed operation. The same source that is to be used for formation of the layer may be used or alternatively a separate source in either the same or a separate chamber may be used.

Disclosed methods can also include a step of directing a particle beam towards the surface of a substrate. The particle beam includes particles, which can also be referred to herein as incident species (once they strike the surface). The particles are generally low impact energy particles. The particles can either be monoatomic or polyatomic. Monoatomic particles have impact energies that are the same as their impact energies. Polyatomic particles on the other hand will have impact energies that are different than their incident energies. The impact energies of the component atomic species of a polyatomic particle will be less than the incident energy of the polyatomic particle. For the case of a singly charged polyatomic particle it is assumed that upon interaction with the substrate or surface atoms, molecular orbital overlap results in complete fragmentation of the polyatomic particle into its component atomic species. The incident energy (V_{inc}, which equals V_{b}+Vₚ) minus the molecular dissociation energy is then partitioned over each component atomic species, or “fragment” according to its mass fraction of the original incident molecular mass. Exemplary impact energies and ranges thereof were discussed above.

Disclosed methods form layers. As discussed above, a layer can refer to material on the surface of a substrate, material at the interface of the substrate (i.e. materials partially implanted into the surface but also exposed as if on the surface), material within the substrate (i.e. materials implanted into the substrate and not exposed at the surface of the substrate), or any combination thereof. In embodiments, methods disclosed herein do not form layers based on nucleation growth mechanisms. Nucleation growth mechanisms fundamentally limit the minimum thickness of a continuous film.

Disclosed methods can change the fundamental growth mechanism from nucleation, which relies on surface mobility effects. Nucleation based methods are typical in processes that utilize incident energies that are less than about 20 eV (e.g., typical sputter deposition methods are from about 7 to about 15 eV; and evaporation methods are less than about 1 eV). Disclosed methods suppress mobility by implantation into a near surface region. The implanted region is kept shallow in order to produce ultrathin altered surface regions. To accomplish this, low energy incident particles, which are difficult in practice to produce at usable beam fluxes, are utilized. Conventional low energy implantation still utilizes particles having KeV energies in order to achieve commercially viable beam currents. The particles utilized are relatively large molecules or clusters so that the fragments have low energies; e.g., silicon doping. For functional engineering of nm scale films, this fragmentation process does not allow sufficient control. Disclosed methods therefore utilize very low incident energies with partitioning over small molecules to achieve controllable, very low implant energy particles.

The material making up the particle beam will be a component of the material of the layer to be formed. In some embodiments, materials from the particle beam will be inserted into a substrate, in which case a mixture of the material from the particle beam and the substrate material will be formed. In some embodiments, layers containing carbon (for example) are formed. In some other embodiments, layers containing hydrogenated carbon (both carbon and hydrogen) are formed. Layers that are formed can have various thicknesses. The thickness of a layer, as that phrase is utilized herein, refers to a measure of the thickness. For example, a measure of a thickness may provide an average thickness, or may provide a property that can be related to the thickness or the average thickness of the layer. For example, layers can be from about sub-monolayer (less than a monolayer of the material) to about 30 Å thick. In some embodiments layers can be from about 15 Å to about 25 Å thick; and in some embodiments, layers can be from about 15 Å to about 20 Å thick.

The present disclosure is illustrated by the following examples. It is to be understood that the particular examples, assumptions, modeling, and procedures are to be interpreted broadly in accordance with the scope and spirit of the invention as set forth herein.

### EXAMPLES

### Example 1

### Exemplary Process Flow

In this example, an inductively coupled RF, gridded ion source was utilized. The process chambers are typically pumped to <10⁻⁶ torr.

The source pre-condition may have operation settings for plasmas formed from inert gas and oxygen or inert gas mixtures individually or sequentially. For example, V_{b}=500V, I_{b}=300 mA with sequential gas mixtures: 10 sccmAr+5 sccm O₂, 15 sccm O₂, 10 sccmAr+5 sccm O₂, 15 sccm Ar with variable durations typically less than 10 mins (for example 3-5 mins at each stage.

The substrate may be obscured by a mechanical shutter or ion gun electronic shutter or rotated such that it is not exposed to any flux from the ion source(s) at any stage prior to pre-deposition etch and deposition stage.

The ion source ignition was done using an inert gas, for example Argon.

A pre-etch stabilization can be carried out by setting the operational parameters to etch conditions. Typically this was an inert gas etch but is not restricted to inert gases. For example V_{b}=300V, I_{b}=500 mA, 15 sccm Ar for 3 mins. The same source that is to be used for surface modifications may be used or a separate source in either the same or a separate chamber may be used.

A pre-layer formation etch can be carried out. It is typically done in an inert gas, but is not limited to inert gases. For example, V_{b}=300V, I_{b}=300 mA, 15 sccm Ar @ 40-80 deg incidence angles (e.g dual angles) from normal. Typically 10-100 Å was removed by a single etch or multiple etches that may include energy, beam current, incident angle, gas composition variation, pulsed operation. The same source that is to be used for surface modifications may be used or a separate source in either the same or a separate chamber may be used.

A pre-layer formation source stabilization may also be carried out. This includes a sequence of gas changes from an inert gas to an inert gas plus a hydrocarbon mixture to a final pure hydrocarbon plasma or hydrocarbon plus minority additions of other gases (for example inert gases, other hydrocarbons, or other molecular species containing carbon). The final ion source settings are at low beam voltage and beam current, which are close to, or at deposition values. A plasma bridge neutralizer (PBN) or other beam neutralization device may (or may not) be turned off during the final stage of source stabilization. This is typically a three stage process, but it can be more or less than 3 stages. For example V_{b}=200V, I_{b}=100 mA, PBN 2 sccm Ar, K=2 @ 10 sccmAr+10 sccm C₂H₂, then 5 sccmAr+25 sccm C₂H₂ for 3 mins each stage, no PBN 30 sccm C₂H₂ 5 mins.

The next step in this exemplary method is the actual surface sub-plantation (SSP) step. For a 35 cm ion source with Acetylene (C₂H₂) plasma support gas @ 5-60 sccm gas, typically 25-30 sccm, are pumped to provide a process pressure in the range of 10⁻²-10⁻⁴ torr. The beam voltage is typically 70<V_{b}<180 V (for example 71 or 126V) and the beam current I_{b}<200 mA (for example 65 mA). The deposition angle is typically normal incidence but may be up to <80 degrees from the substrate surface normal. Typical throw distance is 12″ at normal incidence. Parallel grids were used throughout. The PBN neutralizer may be off or on at this stage.

Additional gases may be indirectly or directly introduced to the process. Their function may be to augment a pure gas SSP process or provide a controlled etch rate capability where the etch rate is < rate of formation of modified surface or film. An etch gas may be indirectly introduced from a beam neutralizer (for example a PBN) or through direct introduction into the ion source. In some examples, indirect introduction is utilized, the gases are inert gases introduced at < 15 sccm e.g 1-3 sccm.

Continuous operation of a deposition process would only require the steps prior to surface sub-plantation (for example, source pre-condition, ion source ignition, pre-etch stabilization, pre-layer formation etch, and pre-layer formation source stabilization) periodically as a maintenance procedure (assuming the use of a secondary etch source).

### Example 2

### Bulk SP v SSP Stress, RWTTF and Raman Spectra

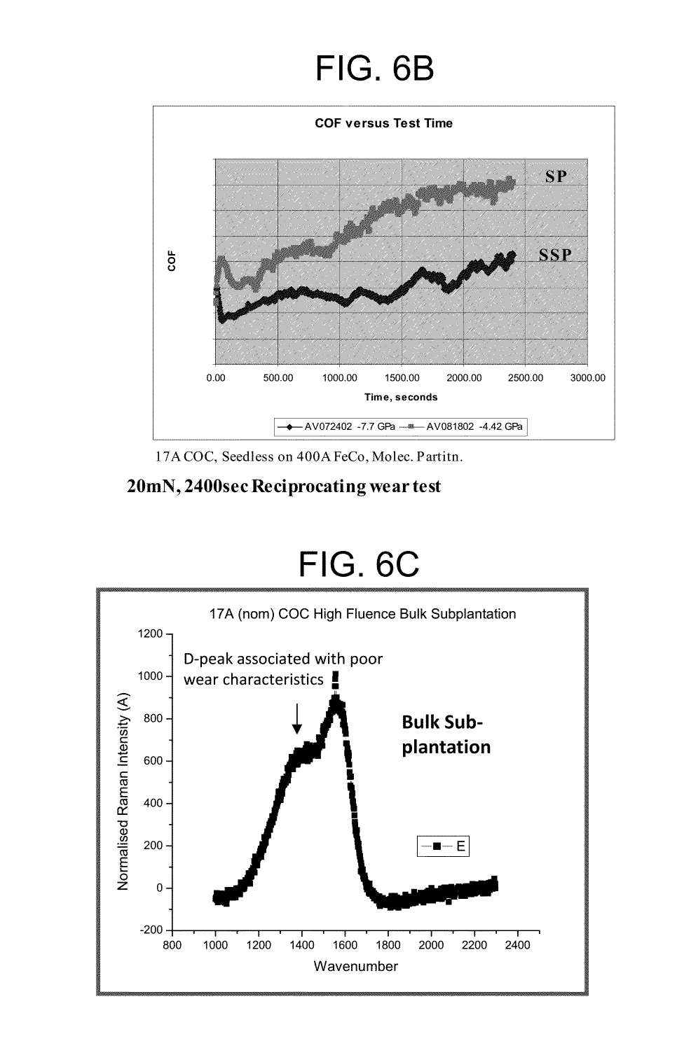

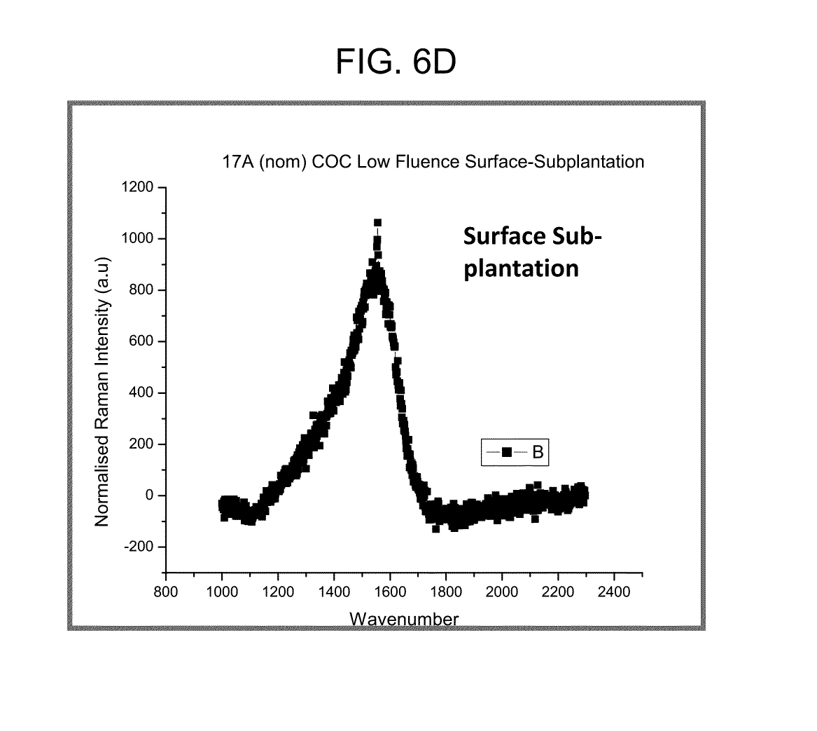

Layers were produced by the acetylene surface sub-plantation method described in Example 1 above, with varying beam voltages at a series of constant beam currents to a nominal 17 Å layer thickness. Prior literature shows that the magnitude of film compressive stress in carbon, hydrogenated carbon films is related to the sp3 bond content. Note the significant increase in the film compressive stress in SSP energy range relative to conventional sub-plantation that is seen in FIG. 6A. This is corroborated by improved wear resistance and coefficient of friction (COF), which is seen in FIG. 6B, and through its Raman chemical signature, which is seen in FIGS. 6C and 6D. FIG. 6C shows the Raman spectrum of conventional implantation and FIG. 6D shows the Raman spectrum of the method disclosed herein. Both samples were annealed at 250° C. for 2 hours in air.

### Example 3

### Effect of Process Type e.g. FCA, P-FCA v SSP in RWTTF Tests

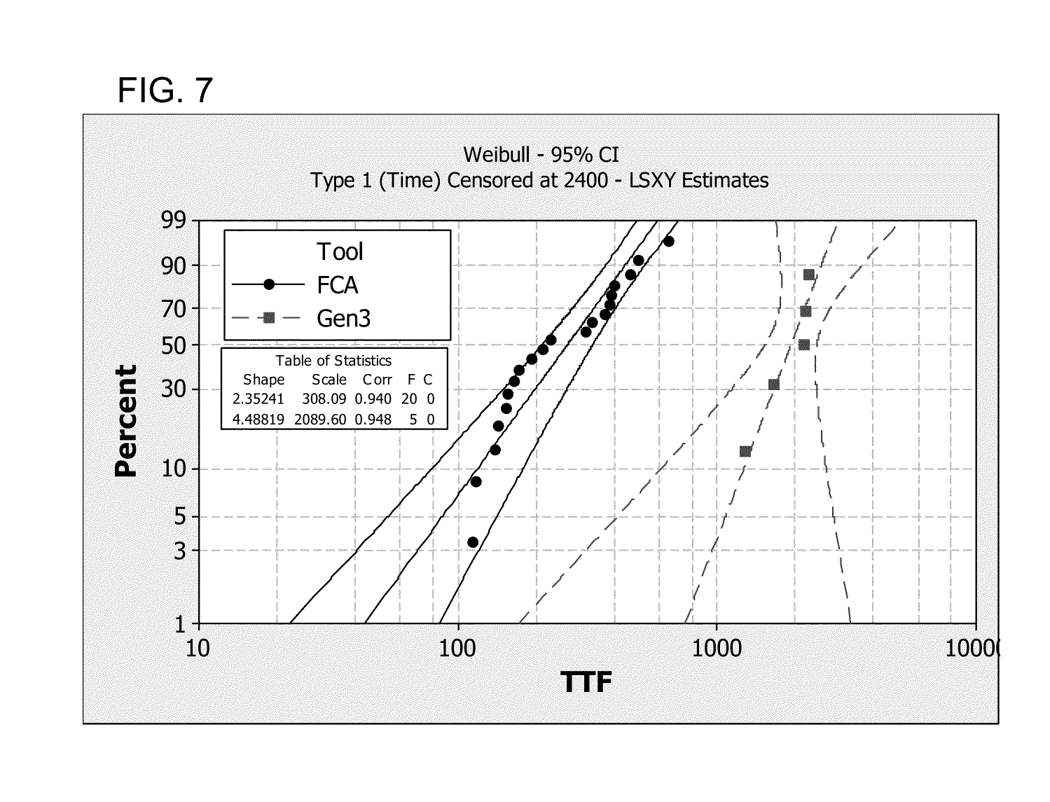

Layers were produced by the acetylene surface sub-plantation method described in Example 1 above at a beam voltage of 126V_{b} and a beam current of 65 mA. FIG. 7 shows significant improvement in the wear resistance over equivalent state of the art overcoat film produced by pulsed filtered cathodic arc technique (pFCA). The 19 Å film produced by the method of Example 1 above without an adhesion layer dramatically out-performs the 11-12 Å carbon film with a 8 Å seed layer film produced with a pFCA method.

### Example 4

### Effect of SSP Energy on Thermal Robustness at Temp Through Vis-Raman D & G peak Intensity

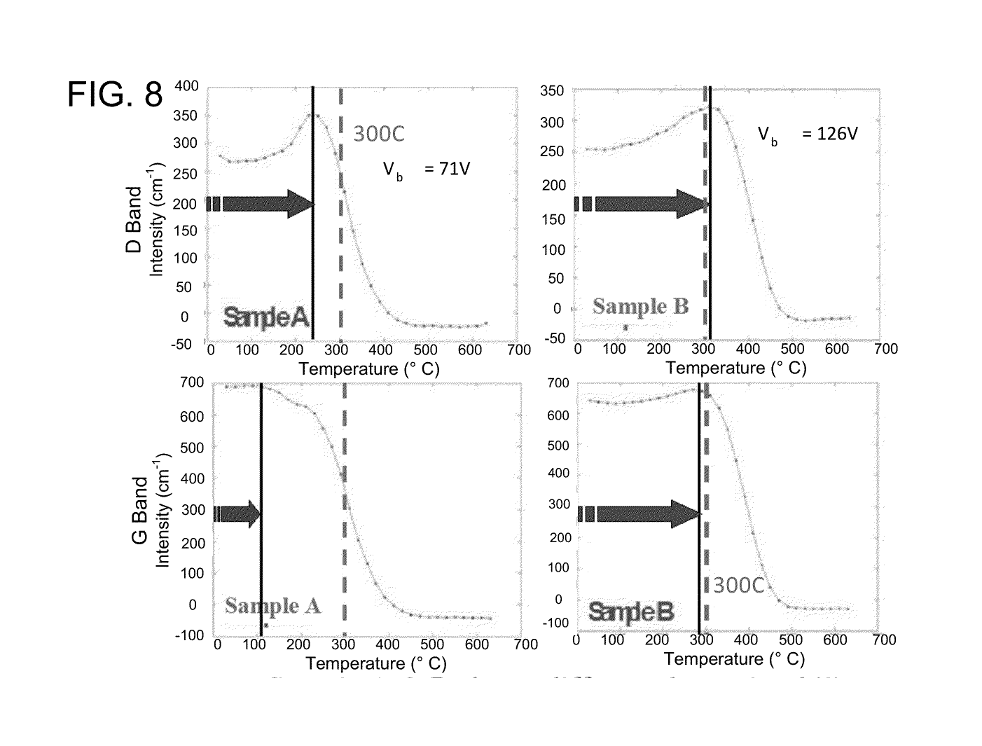

17 Å films were produced by acetylene surface sub-plantation method described in Example 1 above at a beam voltage of 71 V_{b} and 126V_{b} and a beam current of 65 mA. FIG. 8 shows in-situ visible Raman peak intensities at ambient air and temperature. Significant improvement in thermal stability of film Raman signature through variation of beam voltage can be seen. Note the potential correlation to the film compressive stress and potential correlation to sp3 content through Example 2.

### Example 5

### In-Situ Hot RWTTF SSP v P-FCA

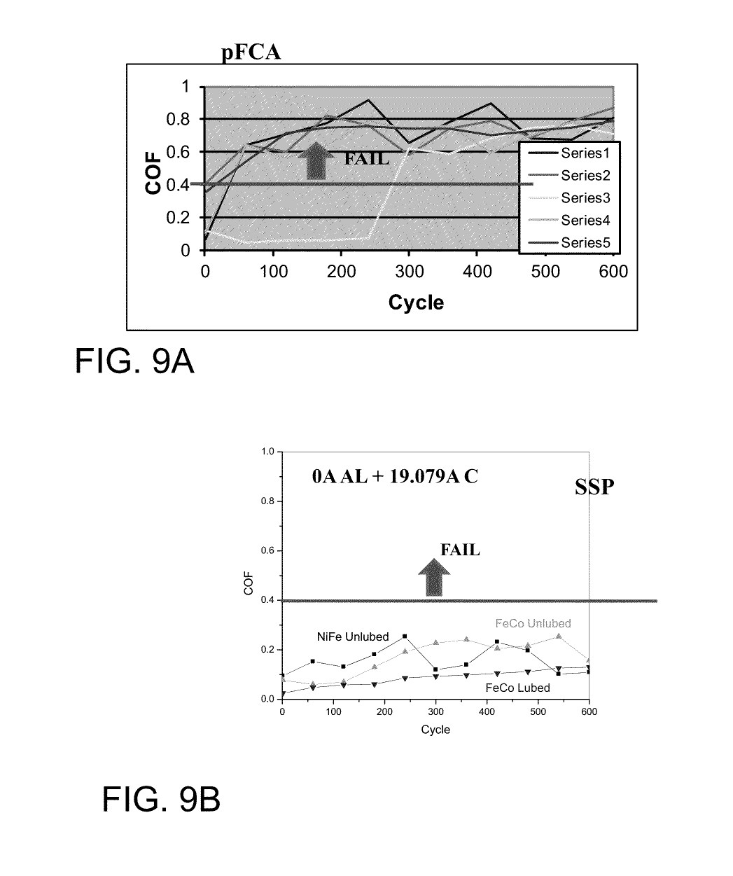

Films were produced by acetylene surface sub-plantation method described in Example 1 above at a beam voltage of 126V_{b} and a beam current of 65mA. FIG. 9A shows in-situ hot RW-TTF tests for films that have 7.9 Å A1 and 15.9 Å C. produced by pFCA. FIG. 9B shows in-situ hot RW-TTF tests for 19 Å Carbon films produced by the method of Example 1 above. As seen from the comparison, significant wear resistance improvement is shown over state of the pFCA films at elevated temperatures.

### Example 6

### Post Anneal Raman Studies of 150/250C 4hr Annealing and Other Annealing Studies, Bulk v SSP v FCA

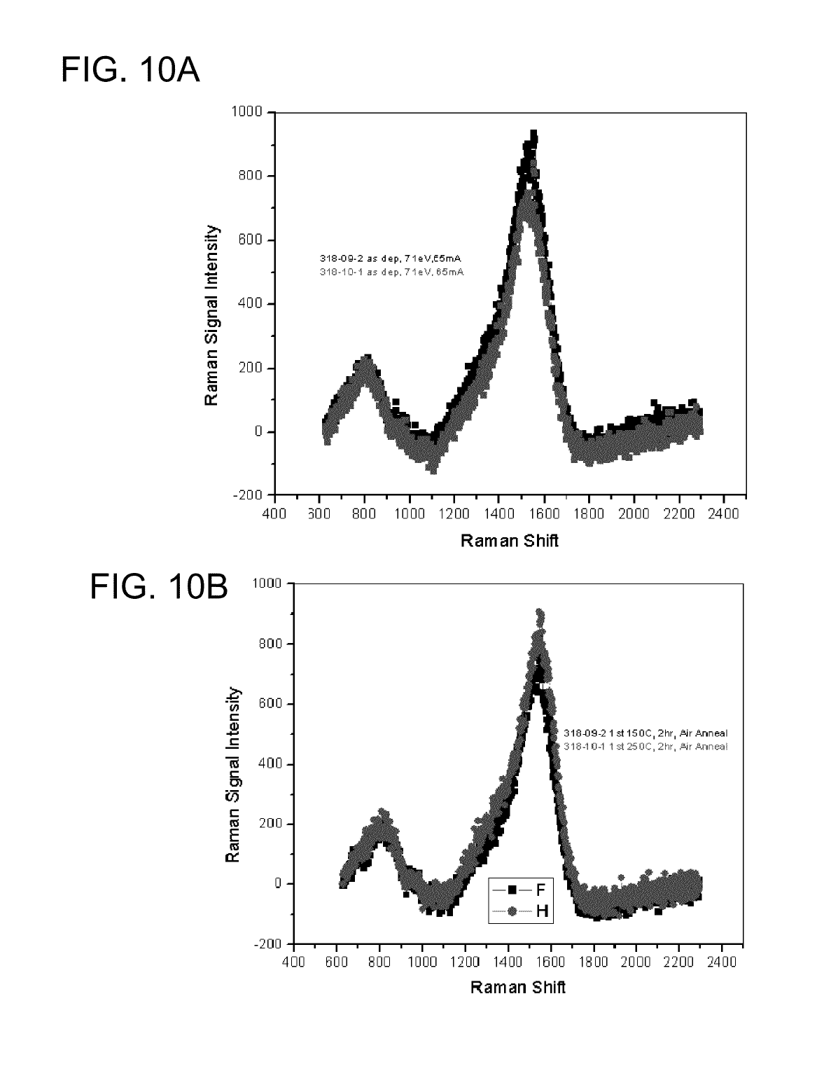

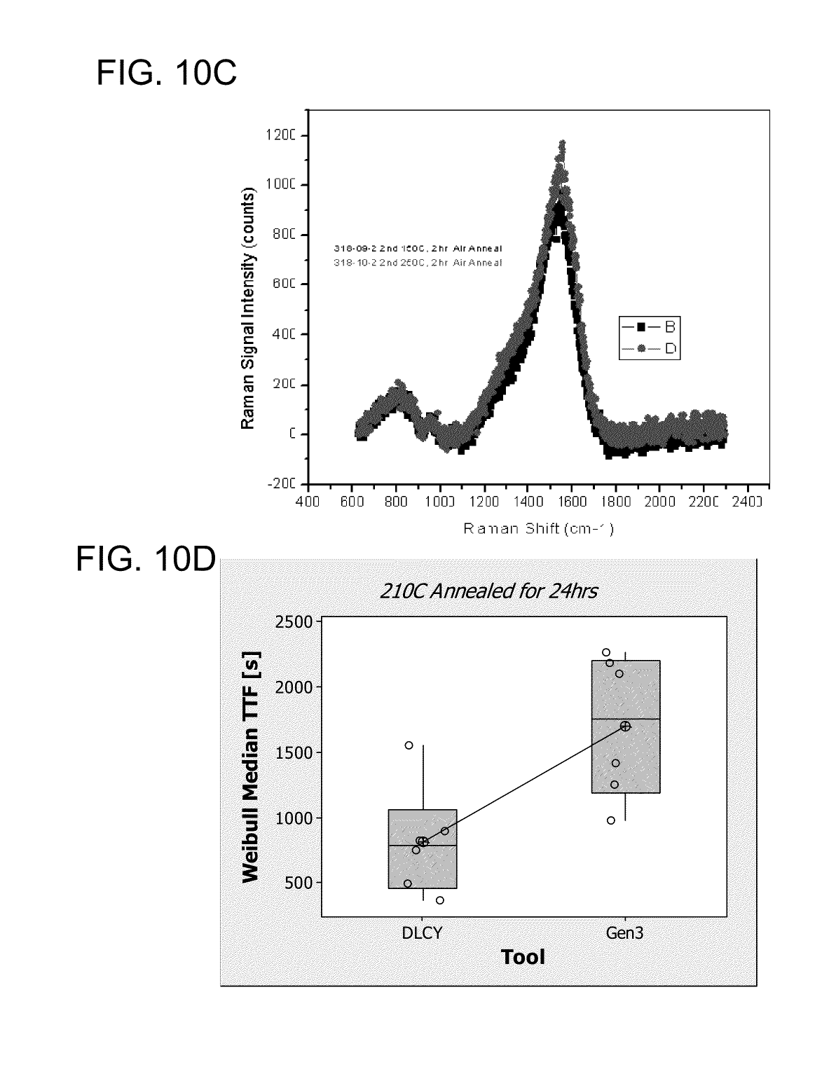

Films produced by acetylene surface sub-plantation method described in Example 1 above at a beam voltage of 126V_{b} and a beam current of 65 mA. FIG. 10A shows the Raman spectrum of the as deposited 17 Å film formed as described in Example 1 above. FIG. 10B shows the film after annealing at 250° C. for two hours and FIG. 10C shows the film after annealing at 250° C. for four hours. No significant change in Raman signature is evident after a cumulative 4 hr anneal in air. This is also shown in FIG. 10D.

### Example 7

### Comparative Wear Box Studies at BAR Level

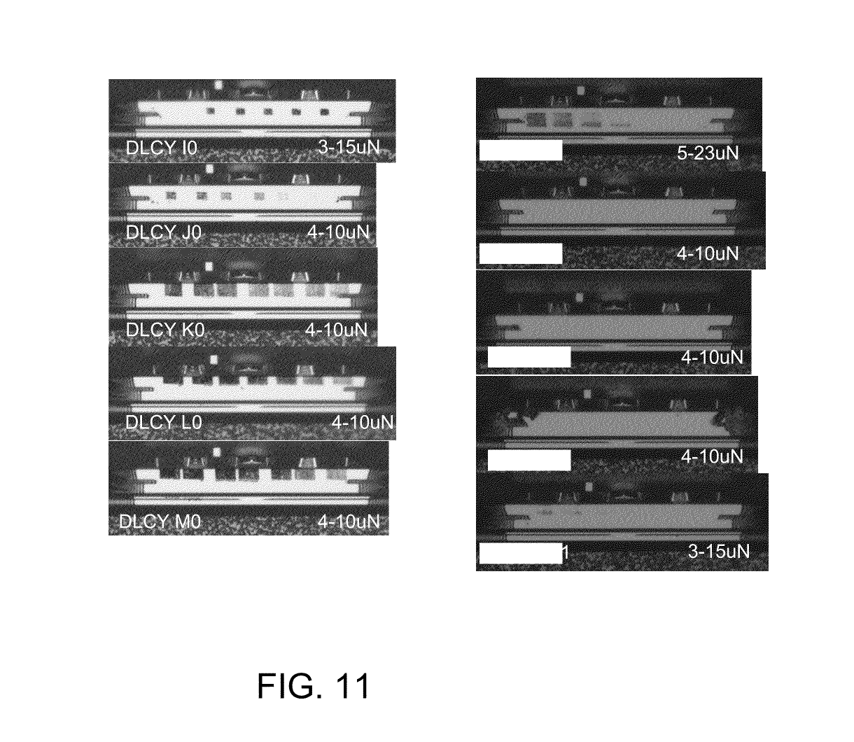

18 Å thick surface sub-planted overcoats were deposited on bar structures. The layers were produced by the method described in Example 1 above with a beam voltage of 71V and a beam current of 65 mA. A bar level Hysitron Wear box and thermal corrosion test was undertaken after the bars were baked for 24 hours at 225° C. in air. Hysitron uses a diamond indenter tip to wear the films at various forces (the ranges of force is noted at the right of the particular sample in μN—the highest forces were applied at the left and the lowest forces at the right). The samples were then annealed in air. Oxidation appears optically as discoloration (or rust). The highest force boxes are at the left, and the lowest force at the right. A comparison is shown with films produced by pFCA (those on the left of FIG. 11) comprised of an 8 A adhesion layer and a 13 A overcoat and those produced by the methods of Example 1 above (those on the right of FIG. 11). A significant improvement in wear resistance is shown for films produced by disclosed techniques relative to pFCA techniques.

### Example 8

### Comparative Friction & Wear Testing at BAR Level

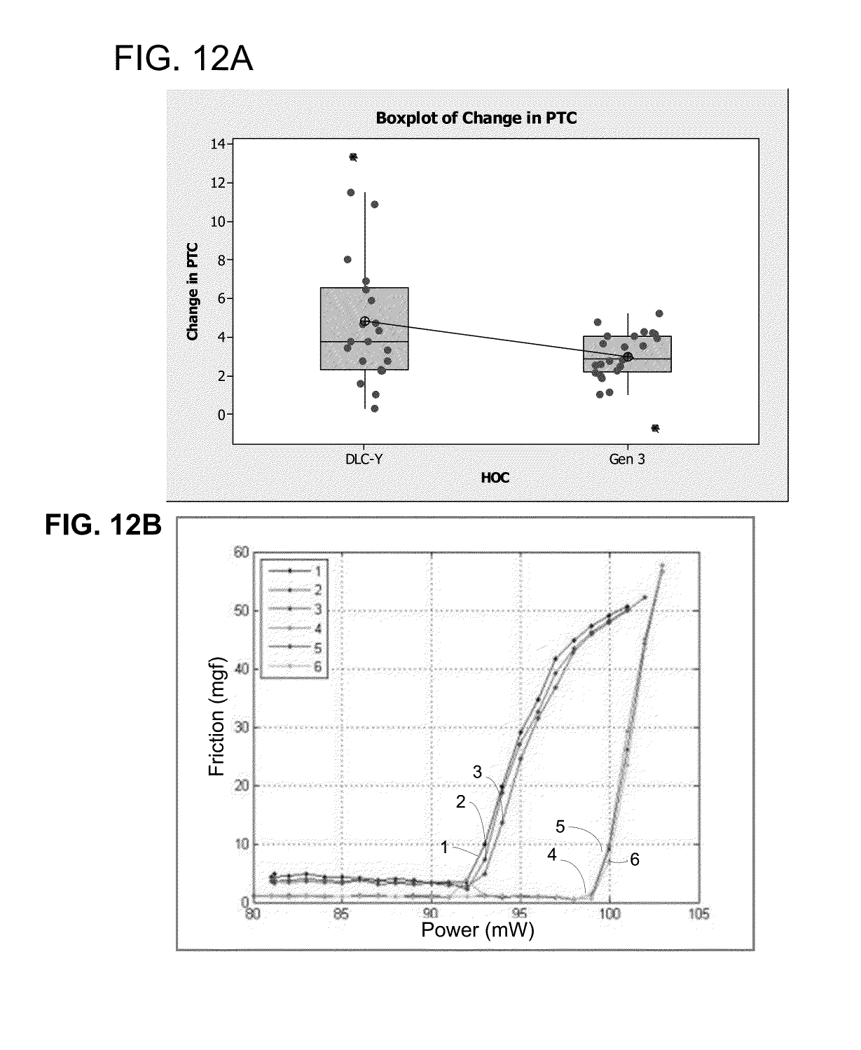

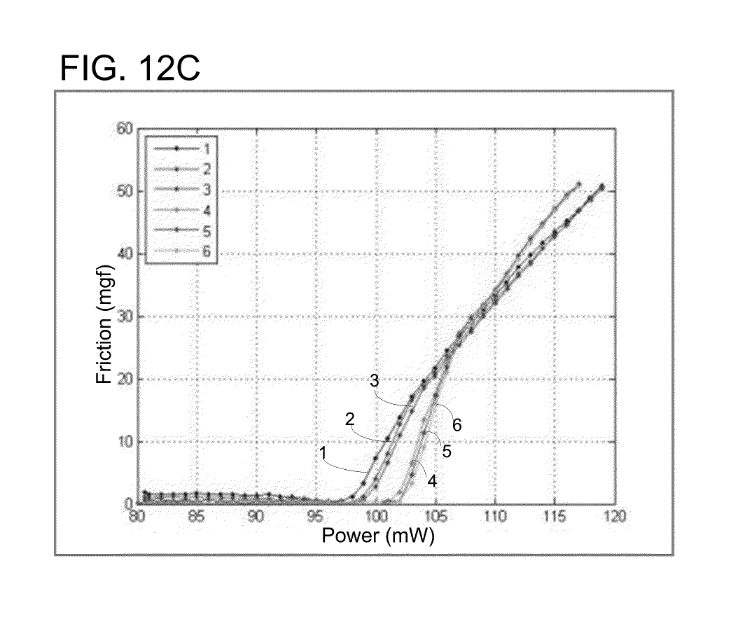

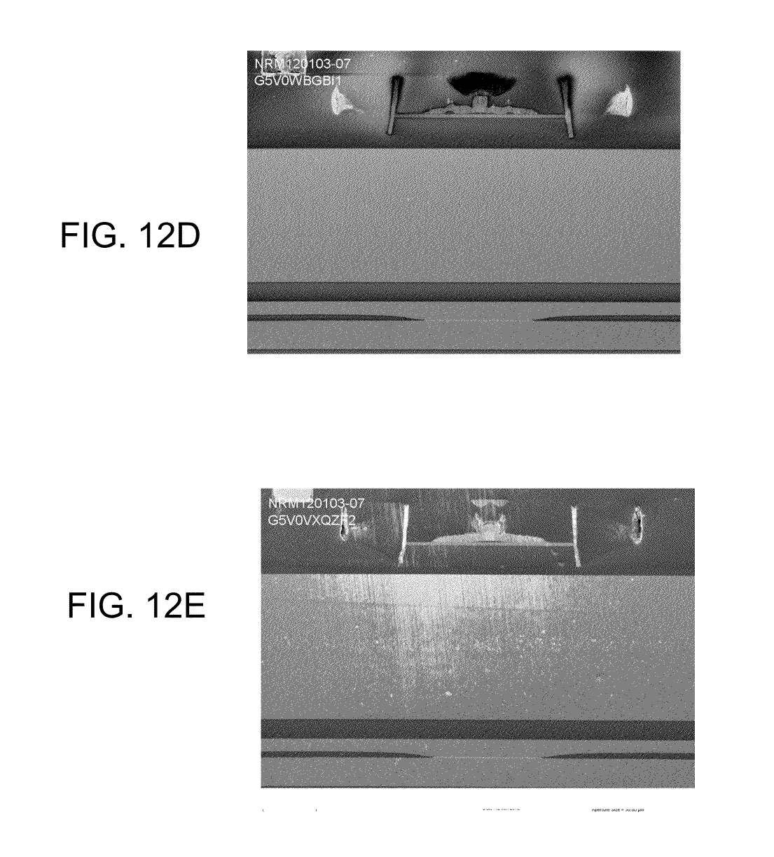

Films were produced by acetylene surface sub-plantation method described in Example 1 above. Head level data demonstrating superior friction and wear characteristics of surface sub-planted hydrogenated overcoat v state of the art pFCA carbon overcoat. FIG. 12A shows the results of advanced friction testing. As seen there, the testing shows that films produced by pFCA are less robust to wear than those produced with SSP as disclosed herein. FIGS. 12B and 12C show the friction slope (rate of change with power) for a film produced with pFCA (FIG. 12B) and a film produced with SSP (FIG. 12C). As seen by the comparison, the slope is lower for the film produced with SSP, showing that there is less wear. FIGS. 12D and 12E show images of a transducer structure with a 19 Å carbon film produced using SSP (FIG. 12D)and a transducer structure with a 28 Å (20 Å carbon and 8 Å adhesion layer) film produced using pFCA (FIG. 12E) after both were burnished. Visible damage can be seen on the pFCA film.

### Example 9

### Comparative at Temp VENA BAR Level Testing

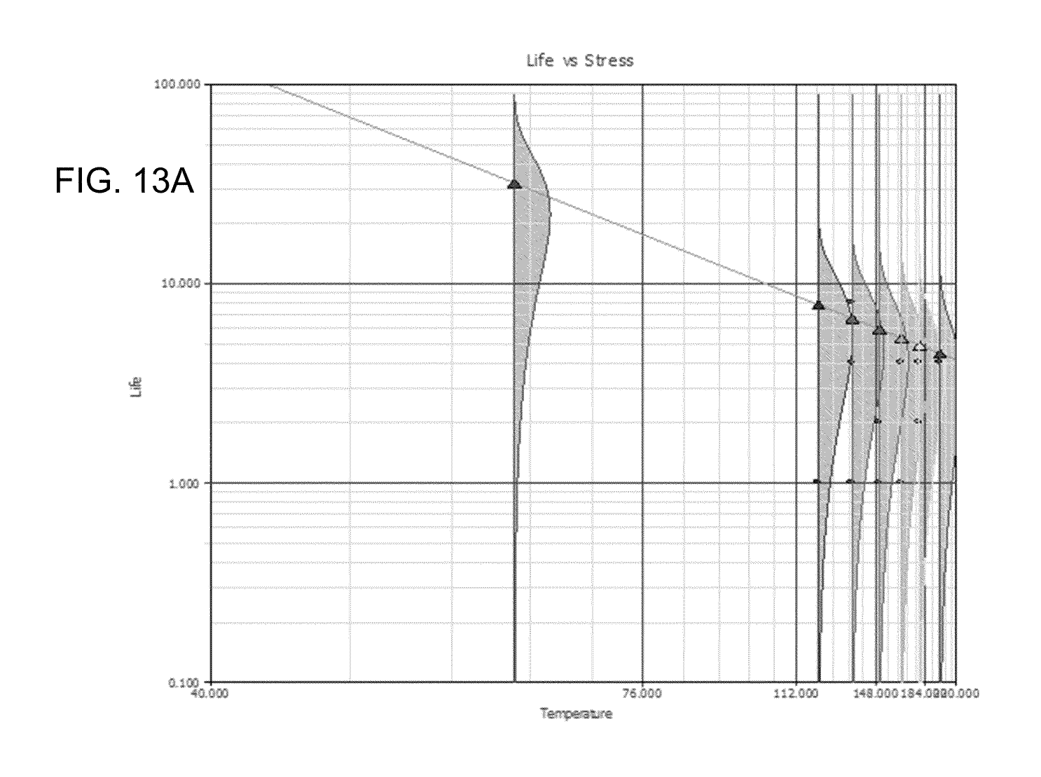

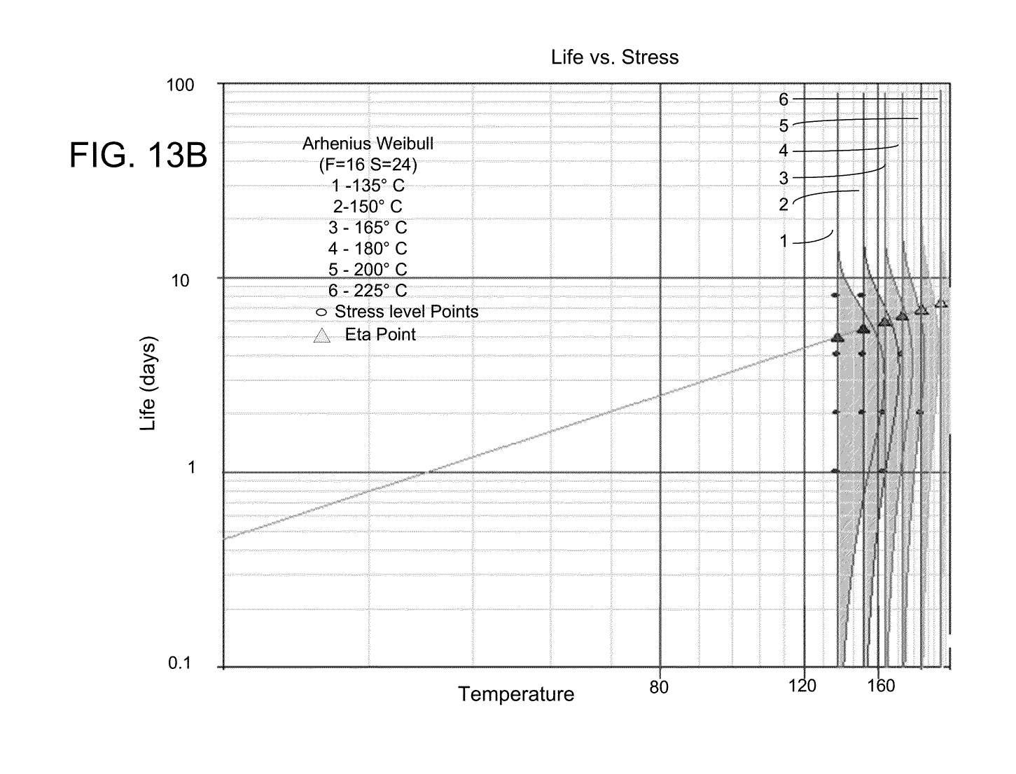

A 17 Å hydrogenated carbon SSP film produced as described in Example 1 above was compared with a film that includes an 8 Å seed layer and 17 Å carbon film produced by pFCA deposition. The films were compared using Head lifetime testing at temperature methods. The testing was pre/post electrical testing with VENA constant clearance testing using “hot advanced air bearing (AAB)” limits to 225° C. The life (days) degrades with increasing temperature (deg C) by Bit Error Rate (BER) metric with the pFCA configuration (FIG. 13A). However, device life increases with temperature for devices coated with the SSP film (FIG. 13B).

### Example 10

### Effect of SSP Deposition Angle

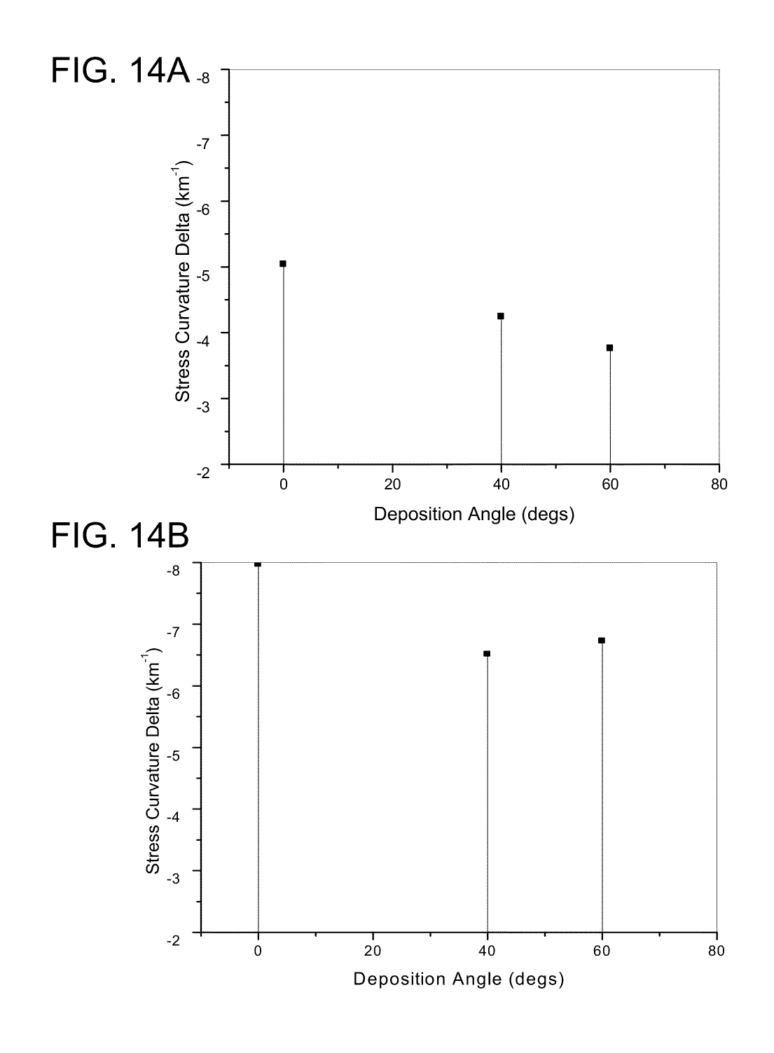

Films of thickness 15 Å and 22 Å were produced by acetylene surface sub-plantation method described in Example 1 above at a beam voltage of 126V_{b}, and a beam current of 65 mA. Films were deposited at normal incidence to the substrate surface and at 40 degrees and 60 degrees from the substrate normal direction. The incident particle energy remained constant throughout these experiments. The geometrically induced reduction in incident particle areal density on the film thickness was compensated for by deposition time based upon XRF thickness calibrations. FIG. 14A shows the film stress as a function of the deposition angle for the 15 Å film and FIG. 14B shows the film stress as a function of the deposition angle for the 22 Å film. As seen there, the effect of deposition angle was more pronounced for thinner films.

### Example 11

### Effect of SSP Dep Angle (First Collision Exchange Energy Corrected)

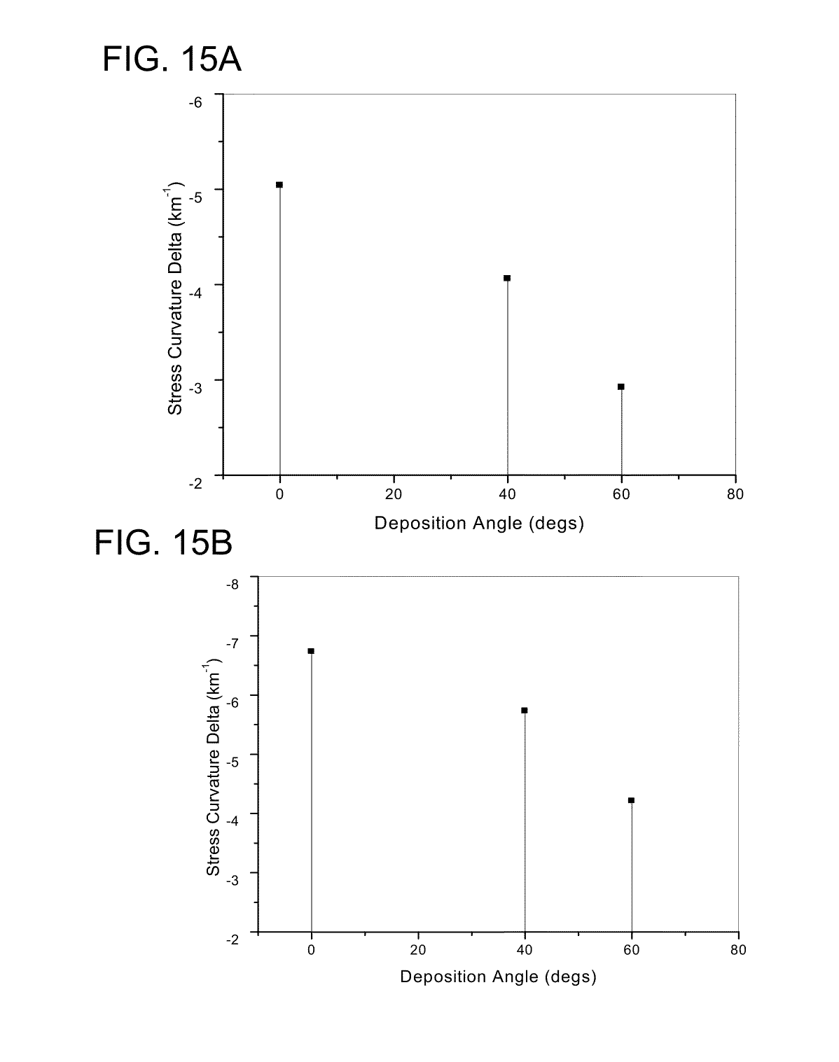

Films of thickness 15 Å and 19 Å were produced by acetylene surface sub-plantation method described in Example 1 above. The films were deposited at normal incidence to the substrate surface, at 40 degrees, and 60 degrees from the substrate normal direction. The incident particle energy was altered as a function of deposition angle to maintain an angularly independent first collision exchange equivalent to that at normal particle incidence angle. The beam current was maintained at 65 mA throughout. The geometrically induced reduction in incident particle areal density on film thickness was compensated for by deposition time based upon XRF thickness calibrations. FIG. 15A shows the film stress as a function of the deposition angle for the 15 Å film and FIG. 15B shows the film stress as a function of the deposition angle for the 19 Å film. The voltage of the beam is shown for each of the angles, as seen there, as the angle becomes greater from normal (0 degrees), the voltage of the beam is increased so that the incident particle energy is constant across all angles.

### Example 12

### Effect of SSP Carbon Film Thickness

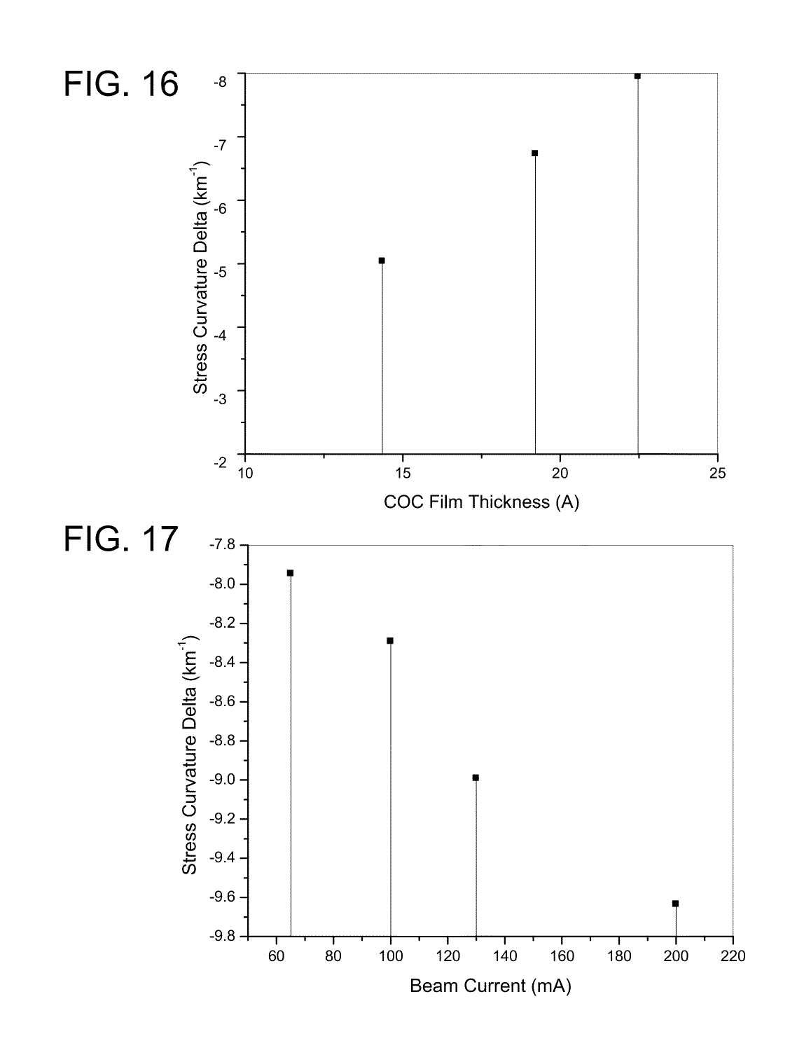

Films of varying thickness were produced by acetylene surface sub-plantation method described in Example 1 above. Films were deposited at normal incidence to the substrate surface. The beam current was maintained at 65 mA throughout. The film thickness was adjusted by varying the deposition time based upon XRF thickness calibrations. FIG. 16 shows the film stress as a function of the thickness of the film. As seen in FIG. 16, the stress increases the thickness of the film increases.

### Example 13

### Surface Sub-Plantation Rate Effects

Films of thickness 21.3±1.2 Å were produced by acetylene surface sub-plantation method described in Example 1 above. Films were deposited at normal incidence to the substrate surface. The beam current was varied at values between 65-200 mA. The film thickness was adjusted by varying the deposition time based upon XRF thickness calibrations. FIG. 17 shows the film stress as a function of beam current. As seen in FIG. 17, the film compressive stress is directly proportional to differential film curvature, measured by a flexus stress tester. Sp3 bond content is known to be related to the magnitude of the compressive stress in carbon films.

Thus, embodiments of METHODS OF FORMING LAYERS are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation.

1-20. (canceled)

21. A method of forming a layer, the method comprising:
pre-conditioning and forming an initial plasma source by:
combining one or more inert gases, one or more reactive gases, or combinations thereof to form a source pre-condition state;
increasing the proportion of or adding one or more reactive gases to the source pre-condition state; and then
decreasing the one or more reactive gases to form the initial plasma source, wherein the initial plasma source includes only the one or more inert gases and does not include any source of carbon;
providing a substrate having at least one surface adapted for forming a layer thereon;
conditioning the initial plasma source by:
adding a source of carbon to the initial plasma source; and
subsequently increasing the amount of the source of carbon and decreasing the amount of the inert gas in the initial plasma source until a plasma source is formed that is 100% source of carbon;
directing a particle beam of the plasma source towards the surface of the substrate, the particle beam comprising particles, wherein the particle beam has an angle of incidence with respect to the substrate, and is configured so that the particles have implant energies that are not greater than about 100 eV;
changing the angle of incidence of the particle beam, the implant energy of the particles, or a combination thereof; and
directing the particle beam towards the surface of the substrate a subsequent time, wherein the particles of the particle beam form a layer on the substrate.

22. The method of claim 21, wherein the particles have implant energies that are less than about 60 eV.

23. The method of claim 21, wherein the particles have implant energies from about 20 eV to about 40 eV.

24. The method of claim 21, wherein the angle of incidence is less than about 80° with respect to the surface of the substrate.

25. The method of claim 21, wherein the angle of incidence is less than about 70° with respect to the surface of the substrate.

26. The method of claim 21 further comprising changing the angle of incidence a plurality of times and implanting material at the plurality of angles αx for a plurality of times tx.

27. The method of claim 26, wherein the angle of incidence is scanned across a range from amin to amax.

28. The method of claim 27, wherein amin can be 0° and amax can be 180°.

29. The method of claim 21, wherein the surface adapted for deposition thereon is etched before the particle beam is directed towards the surface.

30. The method of claim 29, wherein about 10 Å to about 100 Å are removed from the surface adapted for deposition.

31. A method of forming a layer, the method comprising:
pre-conditioning and forming an initial plasma source by:
combining one or more inert gases, one or more reactive gases, or combinations thereof to form a source pre-condition state, wherein the one or more reactive gases comprise O₂;
increasing the proportion of or adding one or more reactive gases to the source pre-condition state; and then
decreasing the one or more reactive gases to form the initial plasma source, wherein the initial plasma source includes only the one or more inert gases and does not include any source of carbon;
providing a substrate having at least one surface adapted for forming a layer thereon;
conditioning the initial plasma source by:
adding a source of carbon to the initial plasma source; and
subsequently increasing the amount of the source of carbon and decreasing the amount of the inert gas in the initial plasma source until a plasma source is formed that is 100% source of carbon;
directing a particle beam of the plasma source towards the surface of the substrate, the particle beam comprising particles, wherein the particle beam has an angle of incidence with respect to the substrate, and is configured so that the particles have implant energies that are not greater than about 100 eV;
changing the angle of incidence of the particle beam, the implant energy of the particles, or a combination thereof; and
directing the particle beam towards the surface of the substrate a subsequent time, wherein the particles of the particle beam form a layer on the substrate.
